(19) United States
(12) Patent Application Publication
(10) Pub. No.: US 2009/0184428 A1
(43) Pub. Date: Jul. 23, 2009

(54) SEMICONDUCTOR DEVICE AND METHOD FOR MANUFACTURING THE SAME

(75) Inventor: Tsuyoshi HAMATANI, Shiga (JP)

Correspondence Address: HAMRE, SCHUMANN, MUELLER & LARSON P.C., P.O. BOX 2902-0902, MINNEAPOLIS, MN, 55402, US

(73) Assignee: PANASONIC CORPORATION, Osaka (JP)

(21) Appl. No.: 12/349,951

(22) Filed: Jan. 7, 2009

(30) Foreign Application Priority Data
Jan. 22, 2008 (JP) 2008-011877

(51) Int. Cl. H01L 21/768; H01L 23/488

(52) U.S. Cl. 257/773; 438/612; 257/E23.023; 257/E21.59

(57) ABSTRACT

A semiconductor substrate, an interwiring insulating film formed on the semiconductor substrate, a first protective film formed on the interwiring insulating film having an opening and a pad metal formed on the opening are provided. A groove is formed in a portion corresponding to a peripheral portion of the pad metal, and the groove is covered with the pad metal. Thus, without decreasing bonding properties, insulation between pads can be maintained as well as cracks in a protective film around pads can be prevented.

### BACKGROUND OF THE INVENTION

1. Field of the Invention

The present invention relates to a semiconductor device and a method for manufacturing the same, and in particular, to a peripheral structure of an external connection electrode (hereinafter “pad”) used for wire bonding in a semiconductor assembly process.

2. Description of Related Art

Traditionally, a semiconductor element is provided with a pad for connecting externally through wire bonding and the like. In the semiconductor device assembly process, wire bonding is performed on each pad, and overextending of wire bonding from the pad has been prevented.

With the progress of miniaturization technologies in recent years, a circuit element has been made smaller. Consequently, the pad has been made smaller in size as well, and bonding techniques such as wire bonding are promoting narrow pitch, resulting in difficulty of confining bonding to each pad.

Whereas, because a protective film to cover each pad is thick, and its strength is maintained, even when wire bonding overextends each pad, the occurrence of cracks in the protective film has been prevented.

Meanwhile, around the peripheral portion of a pad, a problem of wiring delay caused by further miniaturization technologies of a diffusion process is becoming noticeable. In order to reduce the wiring delay, an insulating film having a low permittivity (low-permittivity film) has been used for an insulating film interposed between wiring.

However a low-permittivity film achieving a permittivity of 3.0 or less has far lower mechanical strength than that of a silicon oxide film that conventionally has been used. This causes a significant problem in an assembly process for packaging of a semiconductor element, which is performed after a diffusion process for formation of a semiconductor circuit has been completed, particularly in a wire bonding process. Specific problems are as follows.

If the mechanical strength of an interlayer insulating film is inadequate, the impact load of wire bonding may cause deformation of the interlayer insulating film and/or a protective film when wire bonding is conducted on a pad formed on a semiconductor element. The deformation causes cracks in the interlayer insulating film and/or the protective film, resulting in loss of reliability due to delamination of a pad and/or an interlayer film.

Accordingly, for example, a semiconductor has been proposed in which a metal is formed directly under a pad with an interlayer insulating film sandwiched between the metal and the pad, and the metal and the pad are connected with a plurality of vias (e.g. see JP2000-114309A). With this configuration, the metal contains the impact upon the interlayer insulating film by wire bonding, and the vias prevent the metal from being deformed in the direction of applied force from the impact. Thus, deterioration of mechanical strength of the interlayer insulating film formed directly under the pad can be compensated.

Alternatively, a configuration with a rectangular protective film formed between pads, blocking a pad from extending to an adjacent pad, also has been proposed (see JP2005-294676A).

On the other hand, a planarization technique has been realized in accordance with the diffusion process for further miniaturization, and chemical mechanical polishing (CMP) for planarization has enabled a protective film to be thinner. Conversely, if this protective film is made thicker than a conventional protective film, the thicker a protective film is, the higher the warpage that occurs in a wafer state, since the protective film is made of a harder material than that of other insulating films or a silicon substrate, and its expansion coefficient also is different. Consequently, stress generated by this difference increases. This stress influences a miniaturization process significantly. Thus, thinning of a protective film is highly effective in the miniaturization process. Accordingly, cracks in a protective film have been difficult to prevent with the conventional pad structure, but cracks in the protective film can be prevented by forming no protective film on a pad.

However, an inductance is formed in some devices, for example for analog circuits, and a top metal used for a pad needs to be made far thicker in order to increase inductance. In this case, although cracks in a protective film can be avoided by forming no protective film on the pad, because the top metal used for the pad is thick, the top metal may overextend due to the impact of wire bonding and the like, resulting in higher possibility of causing a short circuit with an adjacent pad. The configuration described in JP2005-294676A prevents such a short circuit, but does not suppress overextending of a top metal.

Moreover, widening of a pad pitch results in a larger chip size, and thus it is not acceptable to widen a pad pitch. Accordingly, it was difficult to prevent cracks in a protective film. Besides, improvement of bonding also is required in accordance with demand for a narrow pad pitch.

### SUMMARY OF THE INVENTION

Therefore, with the foregoing in mind, it is an object of the present invention to provide a semiconductor device that maintains insulation between pads as well as prevents cracks in a protective film around pads without decreasing bonding properties.

In order to achieve the above object, a semiconductor of the present invention includes a semiconductor substrate, an interwiring insulating film formed on the semiconductor substrate, a first protective film formed on the interwiring insulating film having an opening, and a pad metal formed on the opening. A groove is formed in a portion corresponding to a peripheral portion of the pad metal, and the groove is covered with the pad metal.

Furthermore, a method for manufacturing the semiconductor device of the present invention includes the steps of forming an interlayer insulating film on a semiconductor substrate, forming an interwiring insulating film and a metal layer on the interlayer insulating film, forming a first protective film on the metal layer, forming an opening in the first protective film and forming a pad metal in a position of the opening. A groove is formed in a portion corresponding to a peripheral portion of the pad metal in the step of forming the opening, and the groove is covered with the pad metal in the step of forming the pad metal.

### BRIEF DESCRIPTION OF THE DRAWINGS

FIGS. 1A and 1B are views showing a semiconductor device according to Embodiment 1 of the present invention; FIG. 1A is a plan view; and FIG. 1B is a cross-sectional view taken along the line X-Y of FIG. 1A.

FIGS. 2A and 2B are views showing one pad structure; FIG. 2A is a plan view; and FIG. 2B is a cross-sectional view taken along the line X-Y of FIG. 2A.

FIGS. 3A, 3B and 3C are views showing a semiconductor device according to Embodiment 2; FIG. 3A is a plan view; FIG. 3B is an enlarged view of a portion A in FIG. 3A; and FIG. 3C is a cross-sectional view taken along the line X-Y of FIG. 3B.

FIGS. 4A and 4B are views showing one pad structure of FIGS. 3A, 3B and 3C; FIG. 4A is a plan view; and FIG. 4B is a cross-sectional view taken along the line X-Y of FIG. 4A.

FIGS. 5A and 5B are views showing a semiconductor device according to Embodiment 3; FIG. 5A is a plan view; and FIG. 5B is a cross-sectional view taken along the line X-Y of FIG. 5A.

FIGS. 6A and 6B are views showing a semiconductor device according to Embodiment 4; FIG. 6A is a plan view; and FIG. 6B is a cross-sectional view taken along the line X-Y of FIG. 6A.

FIGS. 7A and 7B are views showing a semiconductor device according to Embodiment 5; FIG. 7A is a plan view; and FIG. 7B is a cross-sectional view taken along the line X-Y of FIG. 7A.

FIGS. 8A and 8B are views showing a semiconductor device according to Embodiment 6; FIG. 8A is a plan view; and FIG. 8B is a cross-sectional view taken along the line X-Y of FIG. 8A.

FIGS. 9A and 9B are views showing a semiconductor device according to Embodiment 7; FIG. 9A is a plan view; and FIG. 9B is a cross-sectional view taken along the line X-Y of FIG. 9A.

FIGS. 10A and 10B are views showing a semiconductor device according to Embodiment 8; FIG. 10A is a plan view; and FIG. 10B is a cross-sectional view taken along the line X-Y of FIG. 10A.

FIGS. 11A and 11B are views showing one example of a conventional semiconductor device; FIG. 11A is a plan view; and FIG. 11B is a cross-sectional view taken along the line X-Y of FIG. 11A.

### DETAILED DESCRIPTION OF THE INVENTION

According to a semiconductor device of the present invention and a method for manufacturing the same, while a pad metal has a necessary thickness in a groove, the thickness in the protruding portion is thin relative to the surface of a first protective film. That is, the apparent thickness relative to the surface of the first protective film is thin, while a substantial thickness is ensured in the peripheral portion of the pad metal. Consequently, overextending of the pad metal sideways, caused by the impact of wire bonding, can be suppressed, and insulation between pads can be maintained. As a result, the characteristics of the semiconductor can be improved.

Moreover, according to the method for manufacturing the semiconductor device of the present invention, without adding a special process or with minimal additional processes, the semiconductor device of the present invention can be manufactured within the same diffusion period as that for a conventional semiconductor device, by modification of only a mask.

In the semiconductor device of the present invention, it is preferable that the groove is formed at least between adjacent pad metals. This configuration is suitable for a case where pads are disposed in one row.

Furthermore, it is preferable that the groove is formed along the entire perimeter of the pad metal. With this configuration, even when pads are disposed in a plurality of rows, insulation between the adjacent pads can be maintained.

Moreover, it is preferable that a second protective film having the same permittivity as, or a different permittivity from, that of the first protective film is formed on the pad metal, and an opening exposing the pad metal is formed in the second protective film. With this configuration, an effect of suppressing overextending sideways of the pad metal can be more enhanced. In addition, even when the second protective film is added, the effect of suppressing overextending sideways of the pad metal by forming the groove also can prevent the second protective film from being broken.

Besides, it is preferable that the interwiring insulating film includes two layers having different permittivities.

Additionally, it is preferable that one part of the groove is covered with the pad metal.

Likewise, it is preferable that an insulating film having the same permittivity as, or a different permittivity from, that of the interwiring insulating film is formed on a portion of the groove that is not covered with the pad metal.

It is also preferable further comprising an interlayer insulating film formed on the semiconductor substrate and a metal layer formed on the interlayer insulating film.

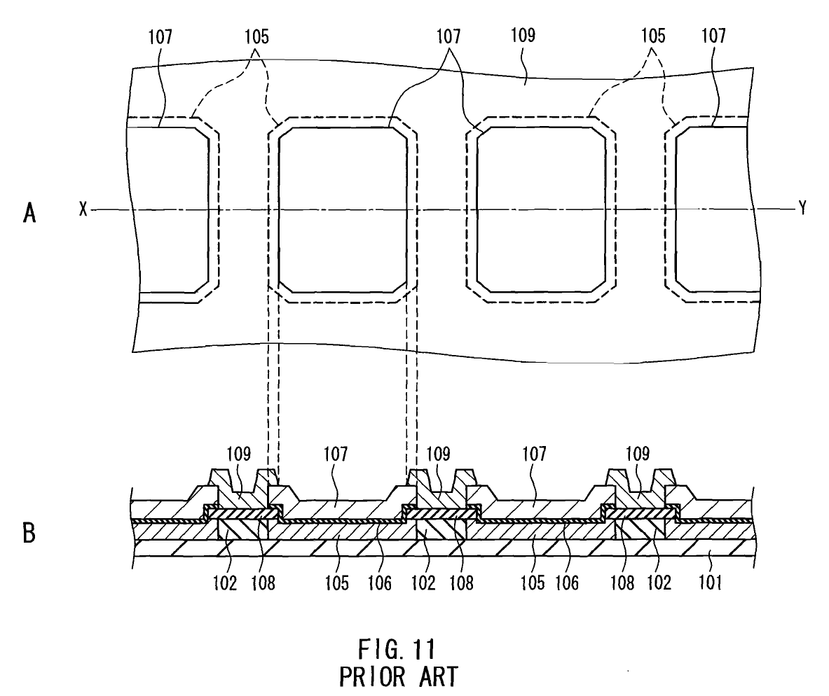

Next, a comparative example will be described in order to easily understand embodiments of the present invention. FIGS. 11A and 11B are views showing one example of a conventional semiconductor device. FIG. 11A is a plan view, and FIG. 11B is a cross-sectional view taken along the line X-Y of FIG. 11A.

In FIGS. 11A and 11B, reference numeral 101 denotes an interlayer insulating film, 102 denotes a first interwiring insulating film, 105 denotes a lower metal layer, 106 denotes a barrier metal layer, 107 denotes a top metal layer, 108 denotes a first protective film and 109 denotes a second protective film.

The peripheral portion of the top metal layer 107 is formed on the flat first protective film 108. With this configuration, when the top metal layer 107 becomes thick, the top metal layer 107 may overextend sideways significantly due to the impact of wire bonding.

Even when the second protective film 109 is formed, the second protective film 109 may be broken due to the impact of wire bonding, since the second protective film 109 cannot be made thick relative to the thickness of the top metal layer 107 in view of stress increase by the warpage.

Hereinafter, the present invention will be described by way of illustrative embodiments with reference to the drawings.

### Embodiment 1

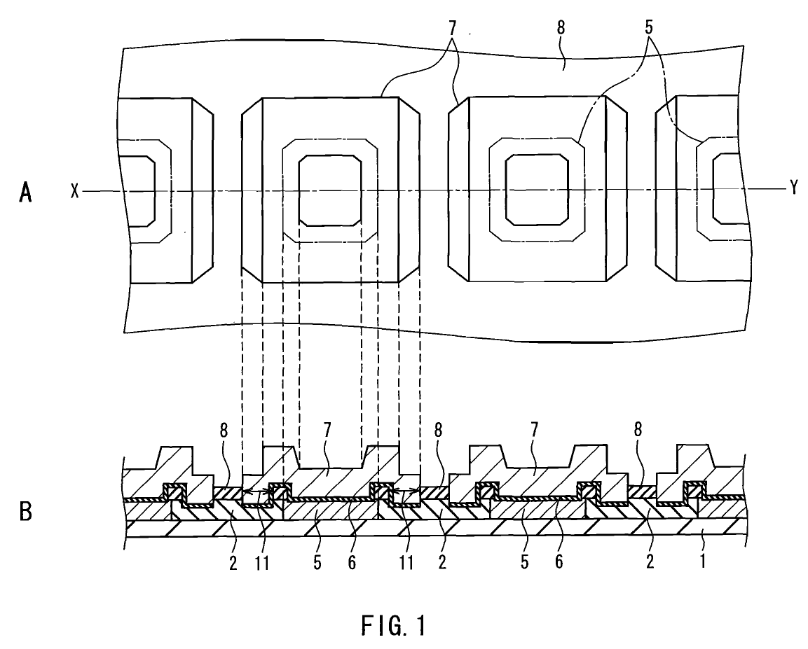

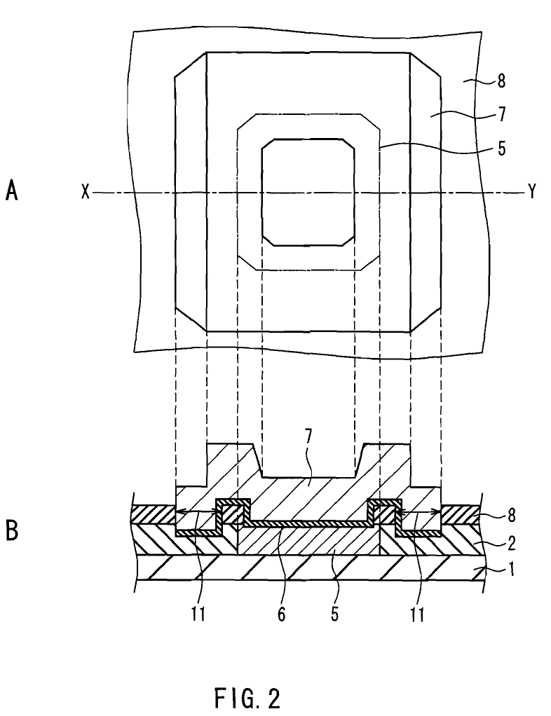

FIGS. 1A and 1B are views showing a semiconductor device according to Embodiment 1 of the present invention and the structure of a semiconductor wafer on which a wiring step of a diffusion process has been completed. FIGS. 1A and 1B are views showing a case where a plurality of pad structures are disposed, and a plurality of pad structures tend to be disposed in this way in practice. FIGS. 2A and 2B are views showing one pad structure of FIGS. 1A and 1B. FIGS. 1A and 2A are plan views, and FIGS. 1B and 2B are cross-sectional views taken along the line X-Y of FIGS. 1A and 2A, respectively.

In FIGS. 1A and 1B, reference numeral 1 denotes an interlayer insulating film, 2 denotes a first interwiring insulating film, 5 denotes a lower metal layer, 6 denotes a barrier metal layer, 7 denotes a top metal layer (pad metal), 8 denotes a first protective film and 11 denotes a groove.

The semiconductor device shown in FIGS. 1A, 1B, 2A and 2B will be described with an illustration of a manufacturing method. As shown in FIG. 1B, the interlayer insulating film 1 is formed on a semiconductor substrate (not shown), on which the first interwiring insulating film 2 is formed. After that, a portion for the lower metal layer 5 that constitutes a pad is opened by etching. Then the lower metal layer 5 is embedded in this opening, forming a damascene interconnect.

Next, the first protective film 8 is formed. The groove 11 is formed in a portion corresponding to the peripheral portion of the top metal layer 7 that constitutes a pad simultaneously with forming an opening in this first protective film 8 by etching. In this embodiment, as shown in FIG. 1A, two sides of the perimeter of the top metal layer 7 face adjacent top metal layers 7. The groove 11 is formed in the position corresponding to these two sides. The width of the groove 11 is about 1 to 10 μm, depending on the thickness of the top metal layer 7 and the diffusion process. The distance between the groove 11 and the lower metal layer 5 is about 0 to 30 μm. The depth of the groove 11 from the surface of the first interwiring insulating film 2 is about 0.1 to 10 μm.

Then, the barrier metal layer 6 and the top metal layer 7 that constitute a pad are formed on the opening and the grooves 11. By doing this, the portions corresponding to the two sides facing the adjacent top metal layers 7 of the perimeter of the top metal layer 7 cover the grooves 11.

The conventional configuration shown in FIGS. 11A and 11B does not have such grooves 11 covered with the top metal layer 7 as shown in FIGS. 1A and 1B, and because the first protective film 108 (FIG. 11B) is flat in the configuration of FIGS. 11A and 11B, when the top metal layer 107 becomes thick, the top metal layer 107 may overextend sideways significantly due to the impact of wire bonding.

Moreover, as shown in FIGS. 11A and 11B, even when the second protective film 109 is formed, the second protective film 109 may be broken due to the impact of wire bonding, since the second protective film 109 cannot be made thick relative to the thickness of the top metal layer 107 in view of stress increase by the warpage.

The configuration of this embodiment, as described above, includes the grooves 11 provided in portions corresponding to the peripheral portion of the top metal layer 7 and the top metal layer 7 sunk into these grooves 11. According to this configuration, in the grooves 11, the thickness of the top metal layer 7 in the protruding portion is thin relative to the surface of the first protective film 8, while a necessary thickness is ensured. That is, the apparent thickness relative to the surface of the first protective film 8 is thin, while a substantial thickness is ensured in the peripheral portion of the top metal layer 7. As a result, overextending sideways of the top metal layer 7 caused by the impact of wire bonding can be suppressed, and insulation between pads can be maintained.

### Embodiment 2

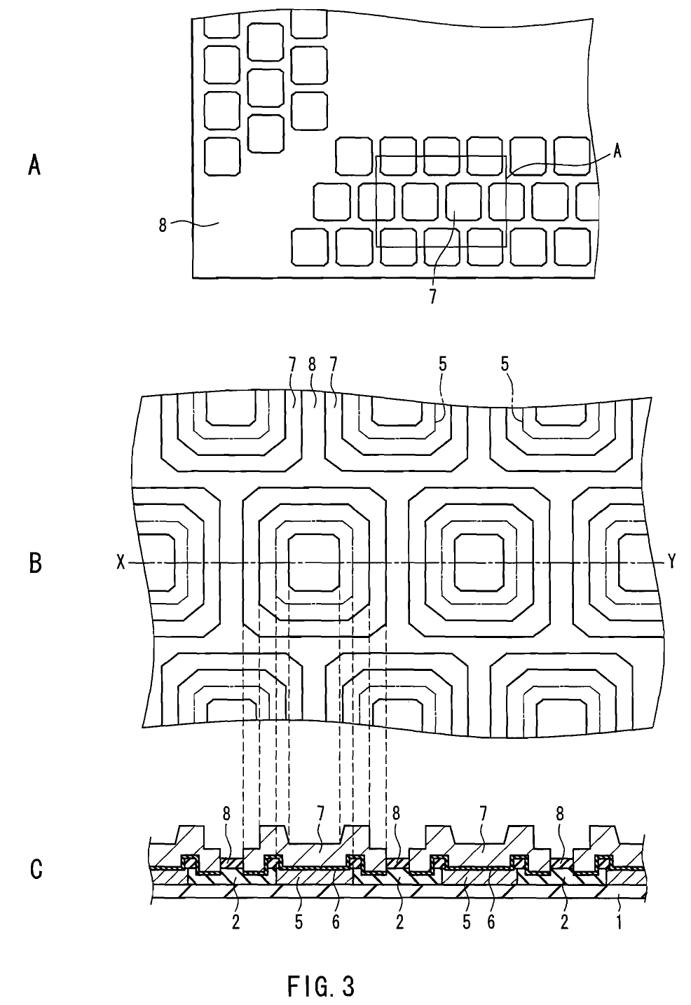

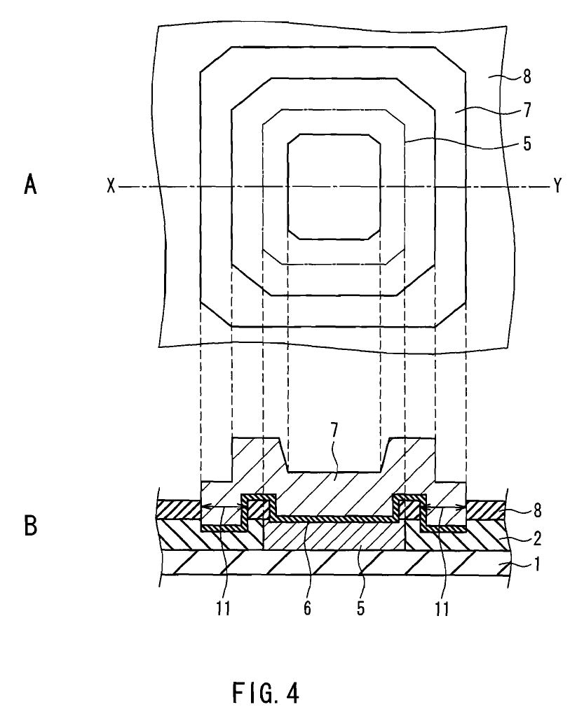

FIGS. 3A, 3B and 3C are views showing a semiconductor device according to Embodiment 2. FIG. 3A is a plan view, FIG. 3B is an enlarged view of a portion A in FIG. 3A, and FIG. 3C is a cross-sectional view taken along the line X-Y of FIG. 3B. FIGS. 4A and 4B are views of one pad structure of FIGS. 3A, 3B and 3C. FIG. 4A is a plan view, and FIG. 4B is a cross-sectional view taken along the line X-Y of FIG. 4A. The same reference numerals are given to elements having the same configuration as that of Embodiment 1, and the explanation is not repeated.

The difference between the configuration of this embodiment and that of Embodiment 1 is that the groove 11 is formed along the entire perimeter of the top metal layer 7. As shown in FIG. 3A, this configuration is suitable for a case where pads are disposed in a plurality of rows. According to this embodiment, in the configuration of pads disposed in a plurality of rows, not only in the direction of electrode pads in the same row, but also in the direction of pads in adjacent rows, overextending sideways of the top metal layer 7 due to the impact of wire bonding can be suppressed. That is, it is advantageous for ensuring insulation between pads around the entire perimeter of the pads.

### Embodiment 3

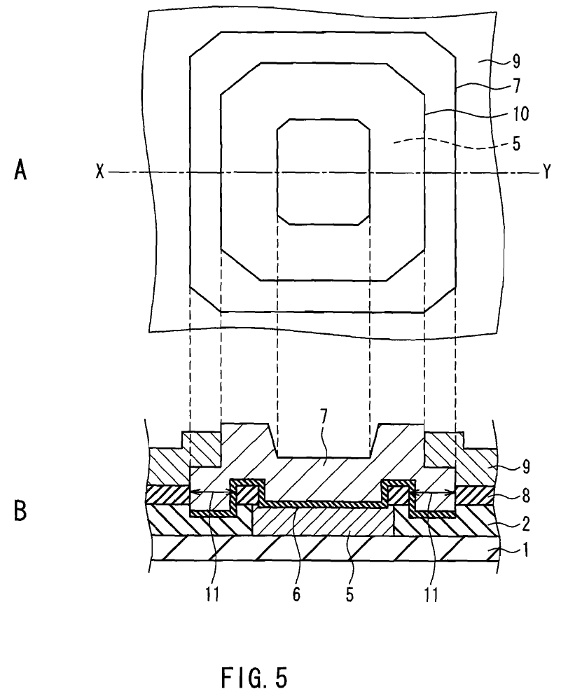

FIGS. 5A and 5B are views showing one pad structure of a semiconductor device according to Embodiment 3. FIG. 5A is a plan view, and FIG. 5B is a cross-sectional view taken along the line X-Y of FIG. 5A. The same reference numerals are given to elements having the same configuration as that of Embodiment 1, and the explanation is not repeated.

A second protective film 9 is formed on the top metal layer 7. An opening 10 is formed in the second protective film 9 in order to expose the top metal layer 7. The second protective film 9 has the same permittivity as, or a different permittivity from, that of the first protective film 8.

In this embodiment, as well as in Embodiment 1, an effect of suppressing overextending sideways of the top metal layer 7 by forming the groove 11 can be obtained. This effect is more enhanced by forming the protective film 9. On the other hand, even when the second protective film 9 is added, the effect of suppressing overextending sideways of the top metal layer 7 by forming the groove 11 also can prevent the second protective film 9 from being broken.

### Embodiment 4

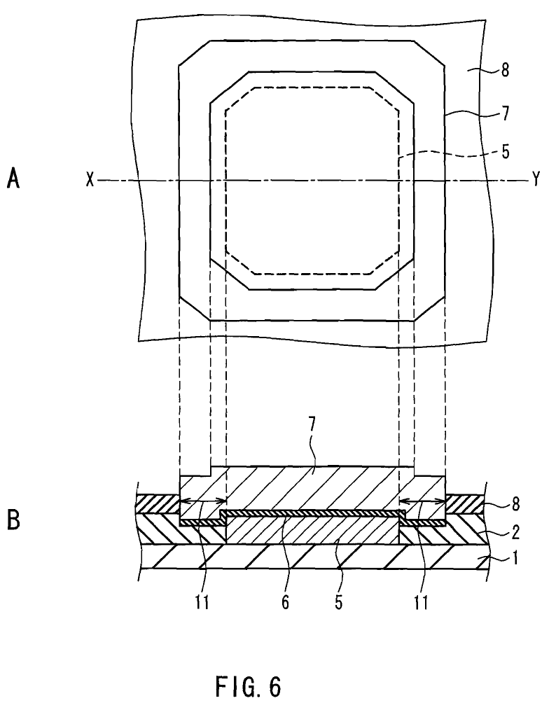

FIGS. 6A and 6B are views showing one pad structure of a semiconductor device according to Embodiment 4. FIG. 6A is a plan view, and FIG. 6B is a cross-sectional view taken along the line X-Y of FIG. 6A. The same reference numerals are given to elements having the same configuration as that of Embodiment 1, and the explanation is not repeated.

In the configuration of FIGS. 6A and 6B, a side surface of the lower metal layer 5 serves also as an internal circumference surface of the groove 11. That is, neither the first protective film 8 nor the first interwiring insulating film 2 is lying between the lower metal layer 5 and the groove 11. In this configuration, the top metal layer 7 can be made flat, and this configuration provides an effect of suppressing overextending of the top metal layer 7 by forming the groove 11 that is the same or more effective than in Embodiment 1.

### Embodiment 5

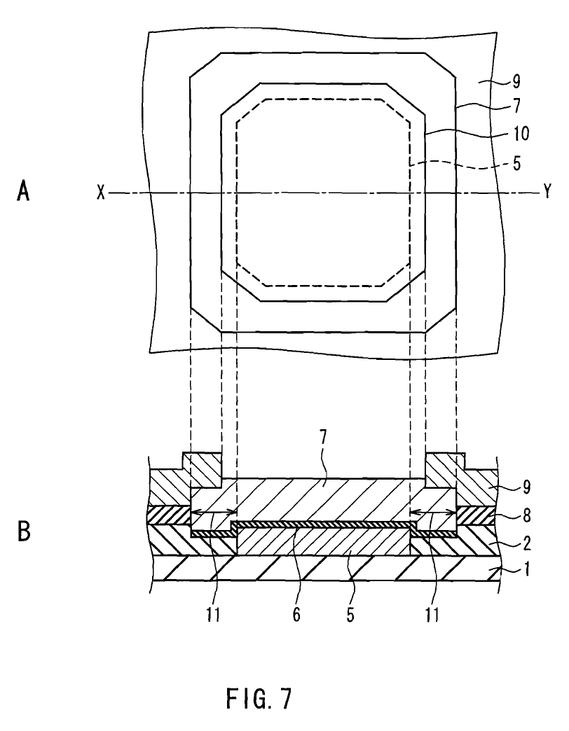

FIGS. 7A and 7B are views showing one pad structure of a semiconductor device according to Embodiment 5. FIG. 7A is a plan view, and FIG. 7B is a cross-sectional view taken along the line X-Y of FIG. 7A. The same reference numerals are given to elements having the same configuration as that of Embodiment 1, and the explanation is not repeated.

FIGS. 7A and 7B show a configuration in which a second protective film 9 is formed on the top metal layer 7 in the configuration of FIGS. 6A and 6B. The configuration of FIGS. 7A and 7B provides, by forming the second protective film 9, an enhanced effect of suppressing overextending of the top metal layer 7, compared to the configuration of FIGS. 6A and 6B. On the other hand, even when the second protective film 9 is added, the effect of suppressing overextending of the top metal layer 7 by forming the groove 11 also can prevent the second protective film 9 from being broken.

### Embodiment 6

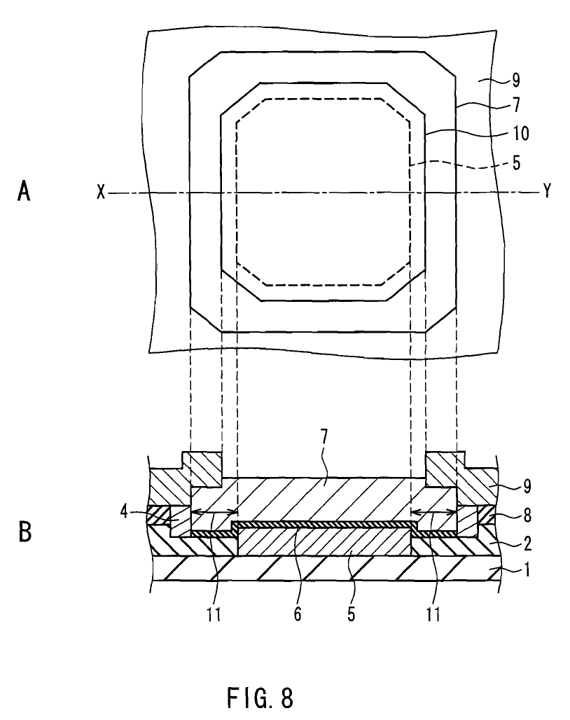

FIGS. 8A and 8B are views illustrating one pad structure of a semiconductor device according to Embodiment 6. FIG. 8A is a plan view, and FIG. 8B is a cross-sectional view taken along the line X-Y of FIG. 8A. The same reference numerals are given to elements having the same configuration as that of Embodiment 1, and the explanation is not repeated.

According to the configuration of FIGS. 7A and 7B, the entire groove 11 is covered with the top metal layer 7. Moreover, according to the configuration of FIGS. 8A and 8B, the groove 11 is covered with a third interwiring insulating film 4 added to the top metal layer 7, and the third interwiring insulating film 4 is lying between the top metal layer 7 and the first protective film 8. The third interwiring insulating film 4 is an insulating film having the same permittivity as, or a different permittivity from, that of the first interwiring insulating film 2.

This configuration provides an effect of suppressing overextending of the top metal layer 7 by forming the groove 11 that is the same or more effective than in the configuration of FIGS. 7A and 7B.

### Embodiment 7

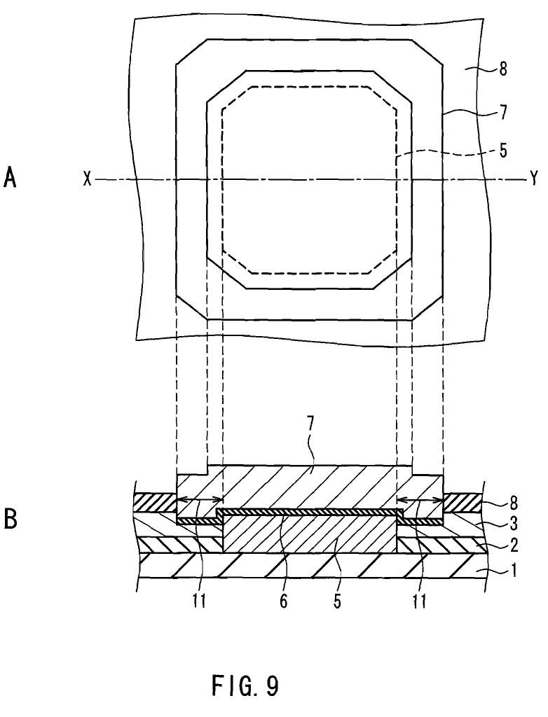

FIGS. 9A and 9B are views showing one pad structure of a semiconductor device according to Embodiment 7. FIG. 9A is a plan view, and FIG. 9B is a cross-sectional view taken along the line X-Y of FIG. 9A. The same reference numerals are given to elements having the same configuration as that of Embodiment 1, and the explanation is not repeated.

In the configuration of FIGS. 9A and 9B, another interwiring insulating film is added to the first interwiring insulating film 2 in the configuration of FIGS. 6A and 6B so as to have two interwiring insulating films. That is, the first interwiring insulating film 2 and a second interwiring insulating film 3 are formed between the interlayer insulating film 1 and the first protective film 8.

With this configuration, reliability is designed to be improved while an effect of suppressing overextending sideways of the top metal layer 7 by forming the groove 11 is obtained, as with the configuration of FIGS. 6A and 6B.

### Embodiment 8

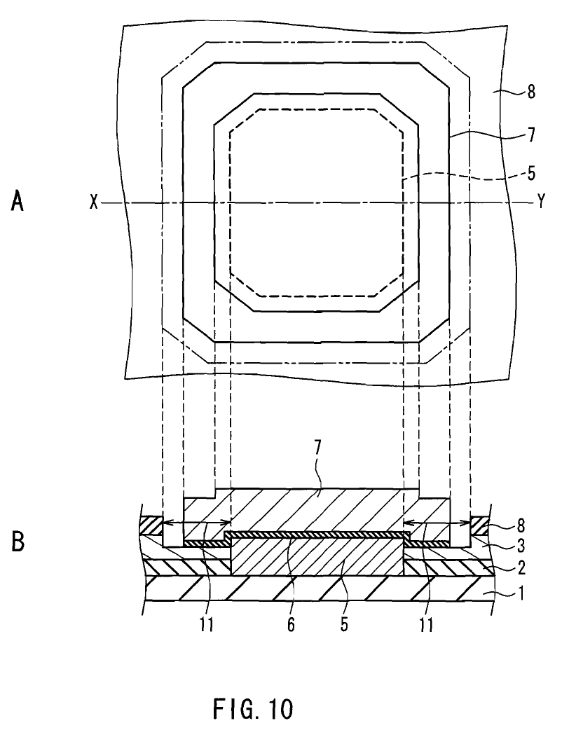

FIGS. 10A and 10B are views showing one pad structure of a semiconductor device according to Embodiment 8. FIG. 10A is a plan view, and FIG. 10B is a cross-sectional view taken along the line X-Y of FIG. 10A. The same reference numerals are given to elements having the same configuration as that of Embodiment 1, and the explanation is not repeated.

According to the configuration of FIGS. 10A and 10B, relative to the configuration of FIGS. 9A and 9B, the width of the groove 11 is broadened, and a gap between the groove 11 and the top metal layer 7 is increased. As in Embodiment 7, high reliability can be maintained by having two insulating films. Moreover, as in the embodiments described above, the effect of suppressing overextending of the top metal layer 7 also can be obtained because the groove 11 is covered with the top metal layer 7.

In this embodiment, since the gap between the groove 11 and the top metal layer 7 is increased, even when the top metal layer 7 overextends sideways, insulation between pads can be ensured as long as the top metal layer 7 is confined in this gap.

Although the embodiments of the present invention are described above, embodiments of the present invention are not limited to those embodiments. One part of a configuration in the embodiments can be replaced with another part of a configuration in other embodiments. For instance, the configuration of FIGS. 2A and 2B may have the third interwiring insulating film 4 lying between the top metal layer 7 and the protective film 8 as the configuration of FIGS. 8A and 8B, or the configuration of FIGS. 10A and 10B may have one insulating film rather than two insulating films: the first interwiring insulating film 2 and the second interwiring insulating film 3.

Furthermore, Embodiments 3 to 8 may include the groove 11 formed in the position corresponding to the two sides of the top metal layer 7 facing the adjacent top metal layers 7 as in Embodiment 1, rather than along the entire perimeter of the top metal layer 7.

This invention is useful for a semiconductor device provided with a pad, because a short circuit between pads and cracks in a protective film around pads can be prevented.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A semiconductor device comprising:
a semiconductor substrate;
an interwiring insulating film formed on the semiconductor substrate;
a first protective film formed on the interwiring insulating film having an opening; and
a pad metal formed on the opening,
wherein a groove is formed in a portion corresponding to a peripheral portion of the pad metal, and
the groove is covered with the pad metal.

2. The semiconductor device according to claim 1,
wherein the groove is formed at least between adjacent pad metals.

3. The semiconductor device according to claim 1,
wherein the groove is formed along the entire perimeter of the pad metal.

4. The semiconductor device according to claim 1,
wherein a second protective film having the same permittivity as, or a different permittivity from, that of the first protective film is formed on the pad metal, and an opening exposing the pad metal is formed in the second protective film.

5. The semiconductor device according to claim 1,
wherein the interwiring insulating film includes two layers having different permittivities.

6. The semiconductor device according to claim 1,
wherein one part of the groove is covered with the pad metal.

7. The semiconductor device according to claim 6,
wherein an insulating film having the same permittivity as, or a different permittivity from, that of the interwiring insulating film is formed on a portion of the groove that is not covered with the pad metal.

8. The semiconductor device according to claim 1, further comprising an interlayer insulating film formed on the semiconductor substrate and a metal layer formed on the interlayer insulating film.

9. A method for manufacturing a semiconductor device, comprising the steps of:
forming an interlayer insulating film on a semiconductor substrate;
forming an interwiring insulating film and a metal layer on the interlayer insulating film;
forming a first protective film on the metal layer;
forming an opening in the first protective film; and
forming a pad metal in a position of the opening,
wherein a groove is formed in a portion corresponding to a peripheral portion of the pad metal in the step of forming the opening, and
the groove is covered with the pad metal in the step of forming the pad metal.
